(19) United States
(12) Patent Application Publication
(10) Pub. No.: US 2010/0025705 A1
(43) Pub. Date: Feb. 4, 2010

(54) HIGH EFFICIENCY LIGHTING DEVICE AND MANUFACTURING METHOD THEREOF

(75) Inventors: Wei-Kai Wang, Shengang Shiang (TW); Su-Hui Lin, Taichung City (TW); Wen-Chung Shih, Taiping City (TW)

Correspondence Address: SNELL & WILMER L.L.P. (Main), 400 EAST VAN BUREN, ONE ARIZONA CENTER, PHOENIX, AZ, 85004-2202, US

(73) Assignee: HUGA OPTOTECH INC., Taichung (TW)

(21) Appl. No.: 12/182,289

(22) Filed: Jul. 30, 2008

(51) Int. Cl. H01L 33/00; H01L 21/00

(52) U.S. Cl. 257/98; 438/69; 257/E33.056

(57) ABSTRACT

A high efficiency luminous device and a manufacturing method thereof are disclosed. The high efficiency luminous device includes a LED structure, a first metal electrode, and a second metal electrode. The LED structure is for emitting light. The first metal electrode is formed on the LED structure, and the first metal electrode has a plurality of first openings therein. The second metal electrode is formed on the LED structure, and the second metal electrode has a plurality of second openings therein. The plurality of first openings and the plurality of second openings allow the light emitted from the LED structure to pass therethrough.

### FIELD OF INVENTION

The present invention relates to a high efficiency luminous device, and more particularly to a high efficiency luminous device having meshed electrodes for improving the Extraction Efficiency.

### BACKGROUND OF THE INVENTION

With the advance of the epitaxy technique and the reduction of the manufacturing cost, use of Light Emitting Diode (LEDs) has been gradually applied in a variety of appliances. For example, LEDs have been used in various electronic devices, such as, mobile phone, multimedia player, and PDA. There is also a high likelihood that LEDs will replace the conventional luminous devices in the near future.

A main issue to popularize the utilization of the LED is to increase its luminous efficiency. It is an important object to reduce the absorption and the consumption of the light by the LED itself.

Currently, the light emitted from the current LED will be absorbed or consumed by the device to a certain degree. For example, the electrodes of the LED dies will block and/or absorb certain level of light rays, which may reduce its luminous efficiency. One of the traditional solutions is to shrink the size of the metal electrodes to reduce the consumption of light. However, the size reduction of the metal electrode will result in a difficulty of performing wire-bonding, even causing a short circuit or an open circuit.

Accordingly, it is advantageous to have a high efficiency luminous device to increase the luminous efficiency and to decrease the consumption of the light inside the device.

### SUMMARY OF THE INVENTION

According to an aspect of the present invention, a high efficiency luminous device and a manufacturing method thereof are provided. The high efficiency luminous device can reduce the light absorption while maintaining the size of the electrode for performing the wire-bonding, and the Extraction Efficiency is therefore increased.

According to another aspect of the present invention, a high efficiency luminous device having elongated portions and a manufacturing method thereof are provided to facilitate a uniform distribution of the electric current.

In an embodiment of the present invention, a method for manufacturing a high efficiency luminous device includes the following steps: providing a LED structure for emitting light; forming a first metal electrode and a second metal electrode on the LED structure; and forming a plurality of first openings and a plurality of second openings respectively on the first metal electrode and the second metal electrode. The plurality of first openings and the plurality of second openings allow the light emitted from the LED structure to pass therethrough.

In another embodiment of the present invention, a high efficiency luminous device includes a LED structure, a first metal electrode, and a second metal electrode. The LED structure is provided for emitting light. The first metal electrode is formed on the LED structure, and the first metal electrode has a plurality of first openings. The second metal electrode is formed on the LED structure, and the second metal electrode has a plurality of second openings. The plurality of first openings and the plurality of second openings allow the light emitted from the LED structure to pass therethrough.

According to one aspect of the present invention, the first metal electrode further includes at least a first elongated portion, and the second metal electrode further includes at least a second elongated portion, wherein the first and the second elongated portions respectively have a plurality of openings.

According to another one aspect of the present invention, the first elongated portion is symmetrically distributed on the LED structure, and the second elongated portion is also symmetrically distributed on the LED structure.

According to a further aspect of the present invention, the first elongated portion and the second elongated portion are alternately arranged.

According to another further aspect of the present invention, the plurality of first openings and the plurality of second openings include at least one of the following shapes: circle, triangle, rectangle, rhombus, and other regular or irregular polygons.

According to one of the aspects of the present invention, the size of the first openings and the second openings is between about 1-10 micrometers.

According to another one of the aspects of the present invention, the first openings and the second openings are uniformly distributed on the first metal electrode and the second metal electrode respectively.

### BRIEF DESCRIPTION OF THE PICTURES

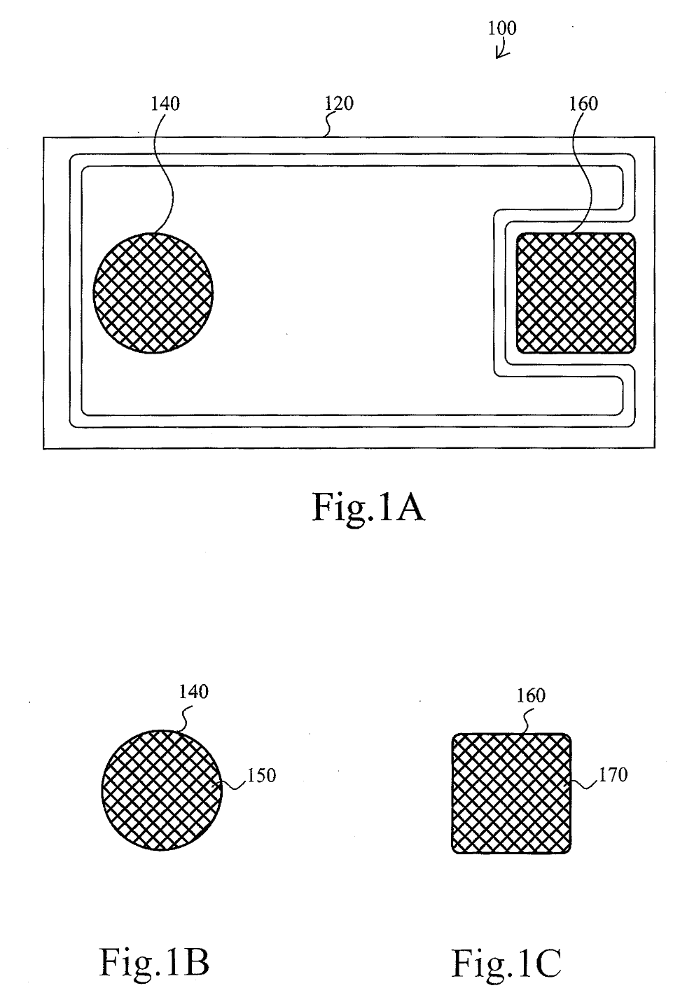

FIG. 1A illustrates a luminous device according to an embodiment of the present invention;

FIG. 1B illustrates a first metal electrode shown in FIG. 1A;

FIG. 1C illustrates a second metal electrode shown in FIG. 1A;

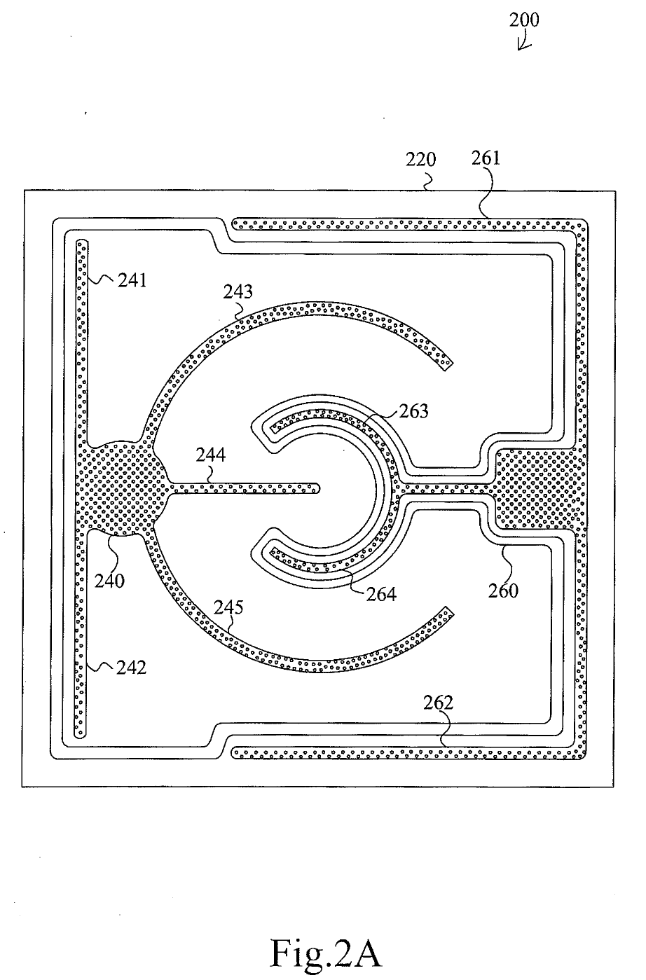

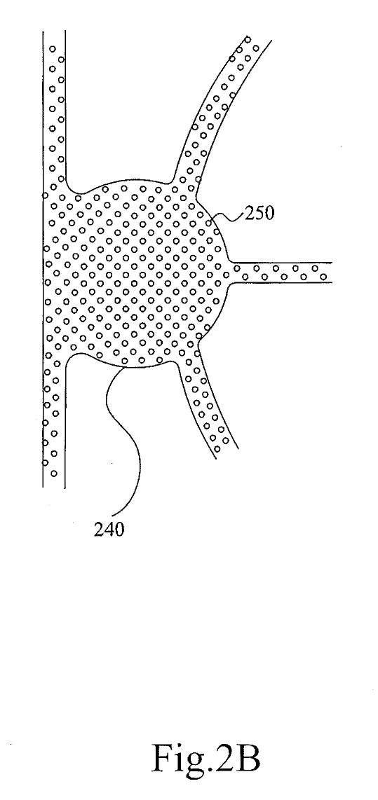

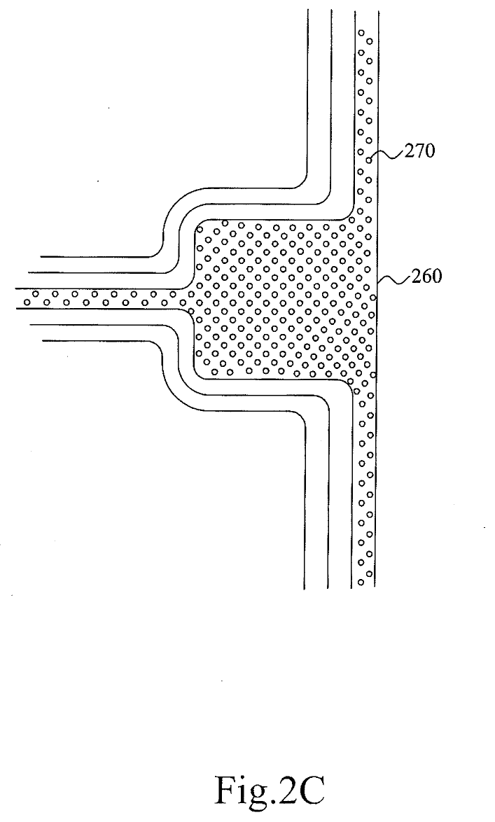

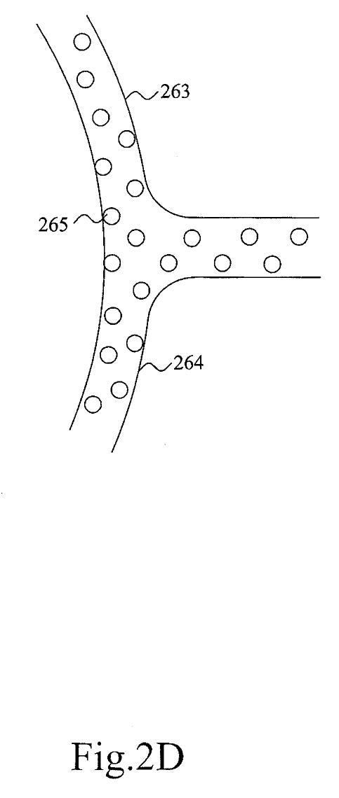

FIG. 2A illustrates another luminous device according to an embodiment of the present invention;

FIG. 2B illustrates a first metal electrode shown in FIG. 2A;

FIG. 2C illustrates a second metal electrode shown in FIG. 2A; and

FIG. 2D illustrates elongated portions shown in FIG. 2A.

### DETAILED DESCRIPTION OF THE INVENTION

FIG. 1A illustrates a luminous device 100 according to an embodiment of the present invention. In this embodiment, the high efficiency luminous device 100 has a LED structure 120, a first metal electrode 140, and a second metal electrode 160. FIG. 1B further illustrates the first metal electrode 140 shown in FIG. 1A, and FIG. 1C further illustrates the second metal electrode 160 shown in FIG. 1A. The first metal electrode 140 is formed on the LED structure 120, and the first metal electrode 140 has a plurality of first openings 150. The second metal electrode 160 is formed on the LED structure 120, and the second metal electrode 160 has a plurality of second openings 170. The plurality of first openings 150 and the plurality of second openings 170 allow the light emitted from the LED structure 120 to pass therethrough. In this embodiment, the first metal electrode 140 and the second metal electrode 160 are meshed electrodes, and the first metal electrode 140 and the second metal electrode 160 respectively have a plurality of rectangular first openings 150 and a plurality of rectangular second openings 170. Compared the conventional solid electrodes, the meshed electrodes have high transmittance while the size of the electrode is also maintained for performing wire-bonding. The plurality of first openings 150 and the plurality of second openings 170 increase the translucent area, and furthermore the plurality of first openings 150 and the plurality of second openings 170 decrease the light absorption area. Namely, the light emitted from the LED structure 120 can pass through the plurality of first openings 150 and the plurality of second openings 170 such that the luminous efficiency of the luminous device 100 is increased. Therefore, the present invention can increase the luminous area and decrease the light absorption area to enhance the Extraction Efficiency without decreasing the size of the metal electrodes. Also the wire-bonding operation of the electrodes will not be impacted.

Besides, the first metal electrode 140 and the second metal electrode 160 in this embodiment are respectively the P, N metal electrodes of the high efficiency luminous device 100. However, those who skilled in the art should understand that the first metal electrode 140 and the second metal electrode 160 of the present invention could be other types of electrodes. In this embodiment, the material of the first metal electrode is selected from any one or any combination of the group consisted of Ni, Au, Cr, Pt, Pd, Cu, W, Fe, Sn, and Ta. The material of the second metal electrode is selected from any one or any combination of the group consisted of Ti, Au, Al, and Cr.

It should be noted that the above figures and description are for illustration only, are not to limit the scope of the present invention. There are still various modifications and changes to the present invention. For example, the shape of the first metal electrode 140 is circular and the shape of the second metal electrode 160 is rectangular in the embodiment, however, the shape of the first metal electrode 140 and the shape of the second metal electrode 160 in other embodiments could be other various shapes, for example, rectangle, rhombus, or other polygons, according to the practical requests. The first openings 150 and the second openings 170 are uniformly distributed on the first mental electrode 150 and the second mental electrode 160 respectively, however, the present invention may still be embodied in many other distributions.

Take the above luminous device 100 as an example; its manufacturing method is described as below. First, a LED structure 120, such as an AlGaInP LED, is provided, where the LED structure 120 generally has an activation layer, an upper cladding layer, a bottom cladding area, a reflection layer, and a transparent layer etc. (not shown in the Figures) to emit light. Then a first metal electrode 140 and a second metal electrode 160 are formed on the LED structure 120 by, for example, a deposition process. Thereafter, the first openings 150 and the second openings 170 are respectively formed on the first metal electrode 140 and the second metal electrode 160 by, for example, chemical etching.

FIG. 2A illustrates another luminous device 200 according to an embodiment of the present invention. In this embodiment, the high efficiency luminous device 200 has a LED structure 220, a first metal electrode 240, and a second metal electrode 260. FIG. 2B further illustrates the first metal electrode 240 shown in FIG. 2A, FIG. 2C further illustrates the second metal electrode 260 shown in FIG. 2A, and FIG. 2D further illustrates elongated portions 263 and 264 shown in FIG. 2A. Referring to FIGS. 2A and 2B, the first metal electrode 240 is formed on the LED structure 220, and the first metal electrode 240 has a plurality of first openings 250 and a plurality of first elongated portions 241, 242, 243, 244, and 245. Referring to FIGS. 2A and 2B, the second metal electrode 260 is formed on the LED structure 220, and the second metal electrode 260 has a plurality of second openings 270 and a plurality of second elongated portions 261, 262, 263, and 264. By means of the first openings 250 and the second openings 270, the luminous area of the electrodes is increased and the light absorption area of the electrodes is decreased. Therefore the Extraction Efficiency is enhanced. Meanwhile, the wire-bonding operation of the electrodes is not impacted. It should be noted that the shape of the first openings 150 and the second openings 170 is circular, however, the shape can be other various shape, for example, triangle, rectangle, rhombus, and other regular or irregular polygons, in other embodiments.

Besides, the first elongated portions 241-245 are symmetrically distributed on the LED structure 220, and the second elongated portions 261-264 are also symmetrically distributed on the LED structure 220, and then the first elongated portions 241-245 and the second elongated portions 261-264 are alternately arranged as shown in FIG. 2A. By means of these elongated portions, the diffusion of the current is enhanced and therefore the current can be uniformly distributed. Referring to FIGS. 2A and 2D, the first elongated portions 241-245 and the second elongated portions 261-264 respectively have a plurality of openings 265. The openings on the elongated portions have the similar function to enhance the Extraction Efficiency. In this embodiment, the size of the first openings 250, the second openings 270, and the openings 265 is about 1-10 micrometer. The design of these openings could be adjusted according to the practical requests. For example, the first openings 250 and the second openings 270 are formed at the same time having the same shape in this embodiment, however, different shapes formed at different time for the first openings 250 and the second openings 270 may be applied in other embodiments. Similarly, those who skilled in the art should understand there are many different modifications to the present invention, for example, the plurality of first openings 250 can be identical in size and shape, or otherwise in different sizes and/or shapes.

The spirit and scope of the present invention can be clearly understood by the above detail descriptions of the prefer embodiments. The embodiments are not intended to construe the scope of the invention. Contrarily, various modifications of the illustrative embodiment, as well as other embodiments of the invention, will be apparent to persons skilled in the art upon reference to this description. It is therefore contemplated that the appended claims will cover any such modifications or embodiments as falling within the true scope of the invention.

1. A method for manufacturing a high efficiency luminous device, comprising:
providing a LED structure for emitting light;
forming a first metal electrode and a second metal electrode on the LED structure; and
forming a plurality of first openings and a plurality of second openings respectively on the first metal electrode and the second metal electrode;
wherein the plurality of first openings and the plurality of second openings allow the light emitted from the LED structure to pass therethrough.

2. The method according to claim 1, wherein the first metal electrode further comprises at least a first elongated portion, and the second metal electrode further comprises at least a second elongated portion, wherein the first and the second elongated portions respectively have a plurality of openings.

3. The method according to claim 2, wherein the first elongated portion is symmetrically distributed on the LED structure, and the second elongated portion is symmetrically distributed on the LED structure.

4. The method according to claim 3, wherein the first elongated portion and the second elongated portions are alternately arranged.

5. The method according to claim 1, wherein the plurality of first openings and the plurality of second openings respectively have a shape selected from a group consisting of at least one of the following shapes: circle, triangle, rectangle, rhombus, regular polygon and irregular polygon.

6. A high efficiency luminous device, comprising:
a LED structure for emitting light;
a first metal electrode formed on the LED structure, and the first metal electrode having a plurality of first openings; and
a second metal electrode formed on the LED structure, and the second metal electrode having a plurality of second openings;
wherein the plurality of first openings and the plurality of second openings allow the light emitted from the LED structure to pass therethrough.

7. The device according to claim 6, wherein the first metal electrode further comprises at least a first elongated portion, and the second metal electrode further comprises at least a second elongated portion, wherein the first and the second elongated portions respectively have a plurality of openings.

8. The device according to claim 7, wherein the first elongated portion is symmetrically distributed on the LED structure, and the second elongated portion is symmetrically distributed on the LED structure.

9. The device according to claim 8, wherein the first elongated portion and the second elongated portions are alternately arranged.

10. The device according to claim 6, wherein the plurality of first openings and the plurality of second openings respectively have a shape selected from a group consisting of at least one of the following shapes: circle, triangle, rectangle, rhombus, regular polygon and irregular polygon.

11. The device according to claim 6, wherein the size of the first openings and the second openings is between about 1 micrometer and 10 micrometers.

12. The device according to claim 6, wherein the first openings and the second openings are uniformly distributed on the first metal electrode and the second metal electrode respectively.

13. The device according to claim 6, wherein the first metal electrode and the second metal electrode are respectively a P-type electrode and a N-type electrode.
